(19) United States
(12) Patent Application Publication
(10) Pub. No.: US 2026/0226657 A1
(43) Pub. Date: Aug. 6, 2026

(54) COMPOSITE SUBSTRATE AND DEVICE

(71) Applicant: NGK INSULATORS, LTD., Nagoya-shi, Aichi (JP)

(72) Inventors: Hiroharu KOBAYASHI, Kasugai-shi (JP); Yosuke SATO, Hashima-Gun (JP); Kyohei ATSUJI, Nagoya-shi (JP)

(21) Appl. No.: 19/629,610

(22) Filed: Mar. 26, 2026

Related U.S. Application Data
(63) Continuation of application No. PCT/JP2024/036491, filed on Oct. 11, 2024.

(30) Foreign Application Priority Data
Nov. 1, 2023 (WO) PCT/JP2023/039435

(51) Int. Cl. C30B 29/40; B32B 18/00

(52) U.S. Cl. CPC C30B 29/403; B32B 18/00

(57) ABSTRACT

Provided is a composite substrate including a support substrate and an AlN single crystal layer bonded to the support substrate. The AlN single crystal layer has, on an exposed surface opposite the support substrate, an X-ray rocking curve full width at half maximum of a (0002) plane of 20 to 350 arcsec, an X-ray rocking curve full width at half maximum of a (10-12) plane of 20 to 500 arcsec, and a defect density of 1.0×10³ to 1.0×10⁷ cm⁻².

### CROSS-REFERENCE TO RELATED APPLICATIONS

This application is a continuation application of PCT/JP2024/036491 filed Oct. 11, 2024, which claims priority of International Patent Application PCT/JP2023/039435, filed Nov. 1, 2023, the entire contents all of which are incorporated herein by reference.

### BACKGROUND OF THE INVENTION

### 1. Field of the Invention

This disclosure relates to a composite substrate including an AlN single crystal layer, and a device.

### 2. Description of the Related Art

In recent years, aluminum nitride (AlN) single crystals have been attracting attention as a base substrate for deep ultraviolet light-emitting elements that use AlN-based semiconductors. For example, AlN, AlGaN, and the like are used as AlN-based semiconductors. These AlN-based semiconductors have a direct transition band structure, making them suitable for light-emitting devices, and can be applied to deep ultraviolet light-emitting diodes (LEDs) and laser diodes (LDs) that can be used in applications such as sterilization.

To achieve high luminous efficiency in such light-emitting devices, a high-quality base substrate with high crystallinity is required.

Therefore, AlN substrates with high crystallinity are being developed as base substrates. Patent Literature 1 (JP6872074B) discloses an aluminum nitride substrate that satisfies the relational expressions c1>97.5% and c2/c1>0.995, where c1 is a c-plane degree of orientation that is defined as a ratio of a diffraction intensity of a (002) plane to a sum of the diffraction intensity of the (002) plane and a diffraction intensity of a (100) plane when a surface layer is subjected to X-ray diffraction measurement from the thickness direction, and c2 is a c-plane degree of orientation that is defined as a ratio of the diffraction intensity of the (002) plane to the sum of the diffraction intensity of the (002) plane and the diffraction intensity of the (100) plane when a site other than the surface layer is subjected to X-ray diffraction from the thickness direction. Patent Literature 2 (JP6872075B) discloses an AlN substrate in which the above-described c1 and c2 satisfy the relational expressions c1>97.5% and c2>97.0%, and also satisfy the relational expressions w1<2.5° and w1/w2<0.995, where w1 is the full width at half maximum in the X-ray rocking curve profile of the (102) plane of the surface layer and w2 is the full width at half maximum in the X-ray rocking curve profile of the (102) plane of a site other than the surface layer.

Further, AlN substrates having a low defect density are being developed as base substrates. Patent Literature 3 (JP2017-117972A) discloses an AlN single crystal laminated body having Al-polarity surfaces on both the front and back sides and a dislocation density of 10⁶ cm⁻² or less. This AlN single crystal laminated body is produced by forming an AlN single crystal layer by hydride vapor phase epitaxy (HVPE) on the N-polarity surface of an AlN single crystal substrate produced by sublimation. Note that a high number of defects means a high number of dislocations.

Moreover, a bonded substrate composed of a support substrate and a Group 13 element nitride crystal substrate has been proposed. For example, Patent Literature 4 (JP7295351B) discloses a bonded substrate composed of a support substrate and a Group 13 element nitride crystal substrate, and discloses that the support substrate and the Group 13 element nitride crystal substrate are directly bonded by activating the bonding surfaces of the Group 13 element nitride crystal substrate and the support substrate by irradiating them with a neutral atomic beam.

### CITATION LIST

### Patent Literature

Patent Literature 1: JP6872074B
Patent Literature 2: JP6872075B
Patent Literature 3: JP2017-117972A
Patent Literature 4: JP7295351B
Patent Literature 5: WO2022/190465
Patent Literature 6: JP2014-086400A

### SUMMARY OF THE INVENTION

There are several possible methods for forming a functional film using an AlN single crystal as a base substrate or base layer. For example, forming a functional film several μm thick on an AlN single crystal substrate that is about 400 to 600 μm thick, and then grinding the AlN single crystal substrate down to a thickness of 100 μm may be considered as a first method. This method allows the functional film to be formed on an AlN single crystal substrate that has good crystal quality, enabling a functional film having good crystal quality to be formed. However, since thick AlN single crystal substrates are not needed for devices, it is desirable to thin the substrate by grinding (for example, to improve the transmittance of an LED). Further, AlN single crystal substrates are expensive, which increases costs. Alternatively, forming an AlN single crystal layer several μm thick on an inexpensive sapphire substrate, and then a functional film on the AlN single crystal layer may be considered as a second method. In this case, due to the lattice constant mismatch between the sapphire substrate and the AlN single crystal layer, the crystal quality of both the AlN single crystal layer and the functional film tends to be poor. Therefore, this method is inexpensive, however, device performance decreases. In consideration of these circumstances, AlN wafers having high crystal quality which can be provided at low cost are demanded.

The inventors have discovered that by bonding, to a support substrate, an AlN single crystal layer having an X-ray rocking curve full width at half maximum of the (0002) plane, an X-ray rocking curve full width at half maximum of the (10-12) plane, and a defect density that each satisfy a predetermined numerical range, it is possible to provide an inexpensive composite substrate in which a high-quality AlN single crystal layer is firmly bonded to a support substrate.

Therefore, an object of the present invention is to provide an inexpensive composite substrate in which a high-quality AlN single crystal layer is firmly bonded to a support substrate.

The present disclosure provides the following aspects.

### [Aspect 1]

A composite substrate comprising:
a support substrate; and
an AlN single crystal layer bonded to the support substrate,
wherein the AlN single crystal layer has, on an exposed surface opposite the support substrate,
an X-ray rocking curve full width at half maximum of a (0002) plane of 20 to 350 arcsec,
an X-ray rocking curve full width at half maximum of a (10-12) plane of 20 to 500 arcsec, and
a defect density of 1.0×10³ to 1.0×10⁷ cm⁻².

### [Aspect 2]

The composite substrate according to aspect 1, wherein the composite substrate has a size of 50 mm or more in diameter.

### [Aspect 3]

The composite substrate according to aspect 1 or 2, wherein the support substrate is composed of one selected from the group consisting of polycrystalline aluminum nitride, sapphire, silicon carbide, quartz, and a Si substrate.

### [Aspect 4]

The composite substrate according to any one of aspects 1 to 3, wherein the AlN single crystal layer is directly bonded to the support substrate.

### [Aspect 5]

The composite substrate according to any one of aspects 1 to 3, further comprising a bonding layer between the support substrate and the AlN single crystal layer, whereby the AlN single crystal layer is indirectly bonded to the support substrate.

### [Aspect 6]

The composite substrate according to aspect 5, wherein the bonding layer includes at least one selected from the group consisting of aluminum nitride, alumina, silicon carbide, silicon dioxide, and tantalum pentoxide.

### [Aspect 7]

The composite substrate according to aspect 4, wherein the support substrate and the AlN single crystal layer contain Ar in a layered region including a bonding interface between the support substrate and the AlN single crystal layer.

### [Aspect 8]

A device comprising the composite substrate according to any one of aspects 1 to 7.

### [Aspect 9]

A method for producing a composite substrate that comprises a support substrate and an AlN single crystal layer bonded to the support substrate, comprising the steps of:
preparing an AlN composite material comprising an AlN single crystal substrate as a seed substrate and an AlN single crystal layer grown on the AlN single crystal substrate;
implanting hydrogen ions from an exposed surface of the AlN single crystal layer to a predetermined depth in the AlN single crystal layer to form a hydrogen embrittlement portion;
bonding the AlN composite material including the hydrogen embrittlement portion to the support substrate to produce a bonded body; and
heating the bonded body to detach the AlN single crystal layer together with the support substrate from the hydrogen embrittlement portion to obtain a composite substrate comprising the support substrate and the AlN single crystal layer.

### BRIEF DESCRIPTION OF THE DRAWINGS

FIG. 1 is a schematic cross-sectional view showing an example of a composite substrate according to the present invention.

FIG. 2 is a schematic cross-sectional view showing production steps of the composite substrate shown in FIG. 1.

FIG. 3 is a schematic cross-sectional view showing another example of the composite substrate according to the present invention.

FIG. 4 is a schematic cross-sectional view showing a configuration of a vapor phase growth apparatus for forming a film by an HVPE method.

### DETAILED DESCRIPTION OF THE INVENTION

### Composite Substrate

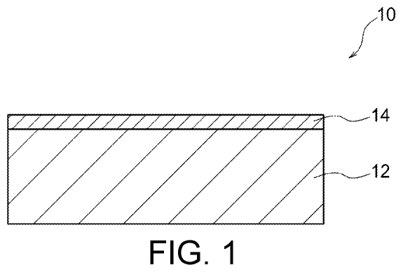

FIG. 1 shows an example of a composite substrate 10 of the present invention. The composite substrate 10 includes a support substrate 12 and an AlN single crystal layer 14 bonded to the support substrate 12. The AlN single crystal layer 14 has, on an exposed surface opposite the support substrate 12, an X-ray rocking curve full width at half maximum (hereinafter referred to as “XRC full width at half maximum”) for a (0002) plane of 20 to 350 arcsec, an XRC full width at half maximum of a (10-12) plane of 20 to 500 arcsec, and a defect density of 1.0×10³ to 1.0×10⁷ cm⁻². By bonding an AlN single crystal layer 14 whose (0002) plane XRC full width at half maximum, (10-12) plane XRC full width at half maximum, and defect density each satisfy the above-described numerical ranges to a support substrate 12, it is possible to provide an inexpensive composite substrate 10 in which a high-quality AlN single crystal layer 14 is firmly bonded to the support substrate 12.

In other words, as described above, there are several possible methods for forming a functional film using an AlN single crystal as a base substrate or base layer. For example, in a first method, a functional film is formed on a thick AlN single crystal substrate, and the AlN single crystal substrate is then grinded. In this method, the functional film can be formed on an AlN single crystal substrate that has good crystal quality. However, since thick AlN single crystal substrates are not needed for devices, it is desirable to thin the substrate by grinding. Moreover, AlN single crystal substrates are expensive, which increases costs. On the other hand, in a second method, the AlN single crystal layer is formed on an inexpensive sapphire substrate, and then the functional film is formed on the AlN single crystal layer. In this method, the crystal quality of both the AlN single crystal layer and the functional film is poor. Therefore, although this method is inexpensive, device performance is reduced. In consideration of these circumstances, there is a demand for AlN wafers that have high crystal quality and that can be provided at low cost.

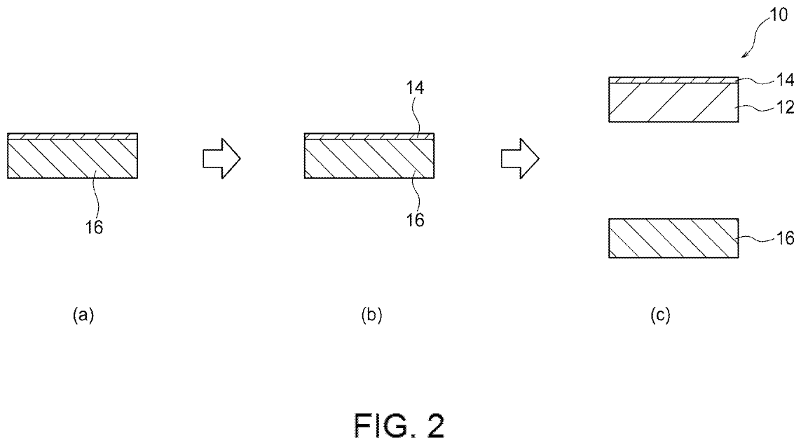

A third possible method is to, as shown in FIG. 2, prepare an AlN single crystal substrate 16 (step (a)), form an AlN single crystal layer 14 on either surface (Al surface or N surface) of the AlN single crystal substrate 16 (step (b)), and transfer the AlN single crystal layer 14 onto a support substrate 12 (which may be cheaper than the AlN single crystal substrate 16) (step (c)). In this method, it is possible to produce a high-quality AlN single crystal layer 14 while keeping costs down. That is, since the AlN single crystal layer 14 is formed on the AlN single crystal substrate 16, there is no lattice constant mismatch, and as a result it is possible to realize a high-quality AlN single crystal layer 14. Further, by transferring the AlN single crystal layer 14 onto the inexpensive support substrate 12 and simultaneously detaching the AlN single crystal substrate 16 instead of grinding it, the expensive AlN single crystal substrate 16 can be reused. As a result, costs can be reduced. However, when the composite substrate 10 thus obtained is used to produce a device, the AlN single crystal layer 14 bonded to the support substrate 12 may detach. In particular, the AlN single crystal layer 14 tends to detach in high-temperature processes (for example, 1000° C. or higher). This problem is successfully solved by the present invention. Specifically, when the XRC full width at half maximum of the (0002) plane, the XRC full width at half maximum of the (10-12) plane, and the defect density of the AlN single crystal layer 14 each satisfy the above-described numerical ranges, the bonding strength with the support substrate 12 is increased. This effect is more pronounced when the size (diameter) of the composite substrate 10 is larger. As a result, according to the present invention, it is possible to provide, at low cost, a composite substrate 10 in which a high-quality AlN single crystal layer 14 (which is unlikely to detach even in high-temperature processes in particular) is firmly bonded to the support substrate 12.

The AlN single crystal layer 14 has, on the exposed surface (Al surface or N surface) opposite the support substrate 12, a (0002) plane XRC full width at half maximum of 20 to 350 arcsec, preferably 100 to 300 arcsec, and more preferably 100 to 280 arcsec. Having a (0002) plane XRC full width at half maximum within this range is advantageous in that when a device is produced no dislocations are introduced into the deposited film, resulting in good performance. Further, the AlN single crystal layer 14 has, on the exposed surface (Al surface or N surface) opposite the support substrate 12, a (10-12) plane XRC full width at half maximum of 20 to 500 arcsec, preferably 200 to 450 arcsec, and more preferably 200 to 400 arcsec. Having a (10-12) plane XRC full width at half maximum within this range is advantageous in that when a device is produced no dislocations are introduced into the deposited film, resulting in good performance. It is preferable that both surfaces (the Al surface and the N surface) of the AlN single crystal layer 14 have a (10-12) plane XRC full width at half maximum within the above-described range and a (0002) plane XRC full width at half maximum within the above-described range. However, since it is not practical to measure the XRC full width at half maximum of the bonding surface of the AlN single crystal layer 14 with the support substrate 12, it is sufficient to measure the XRC full width at half maximum for the exposed surface opposite the support substrate 12, as this can be said to represent the crystal quality of the AlN single crystal layer 14. Measurement of the XRC profiles of the (0002) and (10-12) planes of the AlN single crystal layer 14 can be performed using a general XRD apparatus (for example, D8 DISCOVER manufactured by Bruker-AXS) and accompanying XRD analysis software (for example, “LEPTOS” Ver. 4.03 by Bruker-AXS) based on the procedures described in the examples, which are described later.

The AlN single crystal layer 14 has a defect density of 1.0×10³ to 1.0×10⁷ cm⁻², preferably 1.0×10⁶ to 8.0×10⁶ cm⁻², and more preferably 1.0×10⁶ to 6.0×10⁶ cm⁻², on the exposed surface (Al surface or N surface) opposite the support substrate 12. Having a density within this range is advantageous in that when a device is produced no dislocations are introduced into the deposited film, resulting in good performance. Although it is preferred that both sides of the AlN single crystal layer 14 (Al surface and N surface) have a defect density within the above-described range, since it is not practical to measure the defect density for the bonding surface of the AlN single crystal layer 14 with the support substrate 12, it is sufficient to measure the defect density for the exposed surface opposite the support substrate 12, as this can be said to represent the crystal quality of the AlN single crystal layer 14. It is preferred to measure the defect density over the entire exposed surface, which can be performed by reflection X-ray topography measurement or etch pit evaluation using KOH molten etching. In etch pit evaluation, the etch pit density can be measured by measuring the surface after etching with an optical microscope, a laser microscope, an SEM, or the like. It is noted that the applicable defect density range for each defect evaluation method is limited, and when the defect density is high, evaluation by TEM observation is preferred. Since it is difficult to measure the entire surface area in TEM observation, defect evaluations can be performed by sampling a 50 μm×50 μm area including the center of gravity of the AlN single crystal substrate from the surface, which has been exposed by polishing, and measuring the area with a TEM. There are no particular limitations on the method used to measure such defect density distribution, and for example, X-ray topography can be used to measure a tomographic topography, or section X-ray topography can be used to measure the defect density distribution inside the AlN single crystal substrate. As described herein, defects include threading screw dislocations (TSDs), threading edge dislocations (TEDs), basal plane dislocations (BPDs), and mixed dislocations. Threading means that the dislocation line is approximately parallel to the axis of the hexagonal crystal system. Basal means that the dislocation line is within the basal hexagonal system (0001) plane.

The AlN single crystal layer 14 is preferably an oriented layer oriented in both the c-axis direction and the a-axis direction, and may include a mosaic crystal. “Mosaic crystal” refers to a collection of crystals that do not have clear grain boundaries but whose crystal orientation slightly differs in one or both of the c-axis and the a-axis. Such an oriented layer has a structure in which the crystal orientation is generally aligned in the approximately normal direction (c-axis direction) and the in-plane direction (a-axis direction). With such a structure, it is possible to form a semiconductor layer of excellent quality, in particular excellent orientation, on the AlN single crystal layer 14.

The method for evaluating the orientation of the AlN single crystal layer 14 is not particularly limited, and known analytical methods such as EBSD (electron backscatter diffraction patterns) and X-ray pole figures can be used. For example, when using the EBSD method, an inverse pole figure map and a crystal orientation map of a surface or a cross section orthogonal to the layer surface of the AlN single crystal layer 14 are measured. The crystals of the AlN single crystal layer 14 can be defined as being oriented along two axes, namely, an axis in a substantially normal direction and an axis in a substantially layer surface direction, when the following four conditions are satisfied: in the obtained inverse pole figure map (A) the crystals are oriented in a specific orientation (first axis) in a substantially normal direction to the layer surface, and (B) the crystals are oriented in a specific orientation (second axis) in a substantially in-plane layer surface direction orthogonal to the first axis; and in the obtained crystal orientation map, (C) an inclination angle from the first axis is distributed within ±10°, and (D) the inclination angle from the second axis is distributed within ±10°. In other words, when the above-described four conditions are satisfied, the AlN single crystal layer 14 can be determined as being oriented along the two axes, namely, the c-axis and the a-axis. For example, when the substantially normal direction to the layer surface is oriented along the c-axis, the substantially in-plane layer surface direction may be oriented in a specific orientation (for example, the a-axis) orthogonal to the c-axis. While the AlN single crystal layer 14 may be oriented along the two axes in the substantially normal direction and the substantially in-plane layer surface direction, it is preferred that the substantially normal direction is oriented along the c-axis. The smaller the inclination angle distribution in the substantially normal direction and/or the substantially in-plane layer surface direction, the smaller the mosaicity of the AlN single crystal substrate. The closer the inclination angle distribution is to zero, the closer the AlN single crystal substrate is to a perfect single crystal. Therefore, from the perspective of the crystallinity of the AlN single crystal substrate, the inclination angle distribution is preferably smaller in both the substantially normal direction and the substantially layer surface direction, and is preferably ±5° or less, and more preferably ±3° or less, for example.

The thickness of the AlN single crystal layer 14 is not particularly limited, but is preferably 0.1 to 200 μm, more preferably 0.5 to 150 μm, and further preferably 1.0 to 120 μm.

The support substrate 12 is not particularly limited as long as it is a substrate that can be firmly bonded to the AlN single crystal layer 14. However, the support substrate 12 is preferably a substrate that is cheaper than the AlN single crystal substrate 16 and has a thermal expansion coefficient close to that of the AlN single crystal. Alternatively, the support substrate 12 is preferably a substrate that has high light transmittance and a low refractive index. From this perspective, the support substrate 12 is preferably composed of one type selected from the group consisting of polycrystalline aluminum nitride, sapphire, silicon carbide, quartz, and a Si substrate. The thickness of the support substrate 12 is not particularly limited, but is preferably 200 to 2000 μm, more preferably 300 to 1500 μm, and further preferably 400 to 1000 μm.

The size of the composite substrate 10 is 50 mm or more in diameter, and preferably 100 mm or more or 150 mm or more in diameter. When the diameter of the composite substrate 10 is larger, it is more likely that an effect of improved bonding strength between the support substrate 12 and the AlN single crystal layer 14 will be achieved. While there is no particular upper limit on the diameter of the composite substrate 10, the diameter of the composite substrate 10 is typically 300 mm or less, and more typically 250 mm or less. The composite substrate 10 typically has a circular shape. As used herein, “circular shape” does not necessarily mean a perfect circle, and may mean a roughly circular shape that can be recognized as a circle overall. For example, the substrate may have a shape in which a part of a circle has been cut out for identifying the crystal orientation or for some other purpose (for example, a circular shape including an orientation flat or a notch).

In a preferred mode of the present invention, the AlN single crystal layer 14 is directly bonded to the support substrate 12. In this case, as proposed in Patent Literature 4 (JP7295351B), it is preferable to increase bonding strength by performing surface activation on each bonding surface by irradiating those surfaces with a neutral atomic beam such as an Ar beam. As a result, from the perspective of high bonding strength, it is preferable that the support substrate 12 and the AlN single crystal layer 14 contain Ar in a layered region including a bonding interface between the support substrate and the AlN single crystal layer. This layered region containing Ar can be identified by elemental analysis of a cross section of the composite substrate 10 using an SEM-EDX (energy dispersive X-ray analyzer (EDX) attached to a scanning electron microscope (SEM)). Alternatively, as proposed in Patent Literature 5 (WO2022/190465), the bonding strength may be increased by irradiating each bonding surface with a plasma such as nitrogen gas plasma to activate the surfaces (plasma activation method).

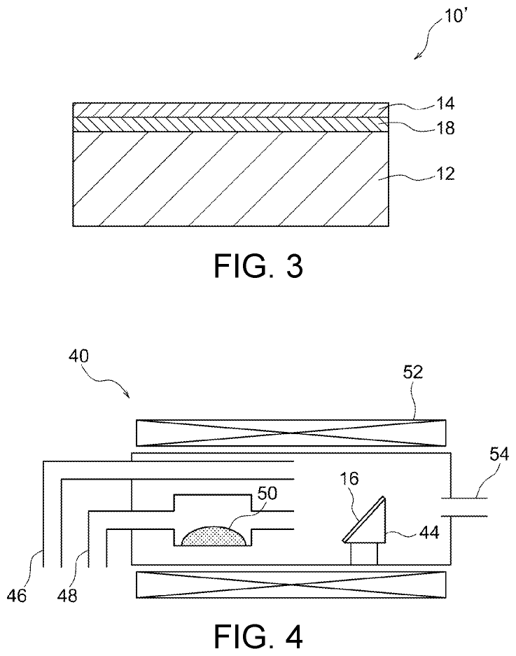

According to another preferred mode of the present invention, like the composite substrate 10′ shown in FIG. 3, a bonding layer 18 may be provided between the support substrate 12 and the AlN single crystal layer 14, so that the AlN single crystal layer 14 is indirectly bonded to the support substrate 12. This enables even greater bonding strength to be achieved. From the perspective of high bonding strength, it is preferable that the bonding layer 18 contains at least one selected from the group consisting of aluminum nitride, alumina, silicon carbide, silicon dioxide, and tantalum pentoxide. After formation of the bonding layer 18, the same process as for the direct bonding described above can be carried out to obtain a bonded body of the support substrate 12/bonding layer 18/AlN single crystal layer 14 with high bonding strength.

### Production Method

As shown in FIG. 2, the composite substrate 10 of the present invention can be produced by preparing an AlN single crystal substrate 16 (step (a)), forming an AlN single crystal layer 14 on either surface (Al surface or N surface) of the AlN single crystal substrate 16 (step (b)), and transferring the AlN single crystal layer 14 onto a support substrate 12 (step (c)).

### (a) Preparation of AlN Single Crystal Substrate

The AlN single crystal substrate 16 that is used is not particularly limited, and may be any known or commercially available AlN single crystal substrate.

### (b) Formation of AlN Single Crystal Layer

The AlN single crystal layer 14 is formed on either surface of the AlN single crystal substrate 16. Therefore, the AlN single crystal layer 14 may be formed on either the Al surface of the AlN single crystal substrate 16 or the N surface of the AlN single crystal substrate 16. The AlN single crystal layer 14 is typically formed by epitaxially growing an AlN single crystal on the surface of the AlN single crystal substrate 16, which serves as a seed crystal. Although any of vapor phase deposition, liquid phase deposition, and solid phase deposition may be used to grow the single crystal, it is preferable to form the AlN single crystal layer 14 using vapor phase deposition. Examples of vapor deposition methods include various CVD (chemical vapor deposition) methods (for example, thermal CVD, plasma CVD, MOVPE, and the like), sputtering, hydride vapor phase epitaxy (HVPE), molecular beam epitaxy (MBE), sublimation, pulsed laser deposition (PLD), and the like, with HVPE being preferred. Examples of liquid-phase deposition methods include solution growth (for example, flux method) and the like. In all of those solid-phase deposition, vapor-phase deposition, and liquid-phase deposition methods, known conditions may be used.

An example of a method for producing the AlN single crystal layer 14 using HVPE is described below. In this method, the AlN single crystal layer 14 is produced by (i) forming the AlN single crystal layer 14 on an AlN single crystal substrate 16, and (ii) polishing the surface of the AlN single crystal layer 14.

### (i) Formation of AlN Single Crystal Layer on AlN Single Crystal Substrate

This step involves forming the AlN single crystal layer 14 on the AlN single crystal substrate 16 as a seed substrate. FIG. 4 shows a vapor phase growth apparatus (hereinafter referred to as an HVPE apparatus) for performing this step using the HVPE method. The HVPE apparatus includes a reactor 40, a susceptor 44, a carrier gas supply source 46, an Al raw material supply source 48, a metal Al powder raw material 50 arranged in the Al raw material supply source 48, a heater 52, and a gas exhaust 54. The AlN single crystal substrate 16 is arranged on the susceptor 44, and AlCl₃ gas obtained by supplying HCl gas to the heated Al raw material supply source 48 and NH₃ gas from the carrier gas supply source 46 are mixed and supplied to the AlN single crystal substrate 16. In this case, the heating temperature of the Al raw material supply source 48 is preferably 500 to 700° C., and more preferably 550 to 650° C. The flow rate ratio of the AlCl₃ gas to the NH₃ gas is preferably 1:1 to 1:500, and more preferably 1:10 to 1:200. The pressure inside the reactor 40 is preferably 1 to 100 Torr, and more preferably 10 to 30 Torr. The growth temperature is preferably 1100 to 1400° C., and more preferably 1150 to 1250° C.

### (ii) Polishing of AlN Single Crystal Layer Surface

The surface of the resulting AlN single crystal layer 14 is mirror-polished. This mirror-polishing is preferably achieved by smoothing the layer surface by lapping with diamond abrasive grains, and then polishing by chemical mechanical polishing (CMP) with colloidal silica or the like. In this way, an AlN composite material is obtained that has a mirror-polished AlN single crystal layer 14 on the AlN single crystal substrate 16.

(c) Transfer of AlN Single Crystal Layer onto Support Substrate

The AlN single crystal layer 14 is transferred from the resulting AlN composite material onto the support substrate 12. This support substrate 12 can be a cheaper substrate than the AlN single crystal substrate 16, which enables costs to be reduced. Further, because transferring the AlN single crystal layer 14 onto the support substrate 12 involves detaching the AlN single crystal substrate 16, it becomes possible to reuse the expensive AlN single crystal substrate 16, which also contributes to cost reduction. That is, if the AlN single crystal substrate 16 is removed by grinding, the AlN single crystal substrate 16 loses its shape, which makes it impossible for the AlN single crystal substrate 16 to be reused. However, if the AlN single crystal substrate 16 is removed by detaching it, the shape of the AlN single crystal substrate 16 can be maintained, making it possible to reuse the AlN single crystal substrate 16.

The transfer of the AlN single crystal layer 14 onto the support substrate 12 involves bonding the AlN single crystal layer 14 to the support substrate 12 and detaching the AlN single crystal substrate 16. Although the AlN single crystal layer 14 and the support substrate 12 may be bonded together after the AlN single crystal substrate 16 is detached, it is preferable to detach the AlN single crystal substrate 16 after bonding the AlN single crystal layer 14 and the support substrate 12. Examples of the detachment method include cutting with a wire saw, laser lift-off (LLO) processing, laser slicing, hydrogen ion implantation (also known as Smart-Cut or ion-cut), sacrificial layer etching, and the like. It is possible to carry out detachment more easily by interposing a release layer composed of graphene, hexagonal boron nitride (h-BN), or the like between the AlN single crystal substrate 16 and the AlN single crystal layer 14.

For example, when using the hydrogen ion implantation method, detachment is preferably performed as follows. First, a hydrogen ion beam is irradiated onto the surface of the AlN single crystal layer 14 using an ion implanter, thereby implanting hydrogen ions into the AlN single crystal layer 14. Next, the AlN single crystal layer 14 into which hydrogen ions have been implanted is bonded to the support substrate 12 (the bonding method will be described later). The resulting bonded body is heat-treated at 400 to 600° C., and the AlN single crystal substrate 16 and the AlN single crystal layer 14 are detached at the depth where the hydrogen ions were implanted. At this time, the portion of the AlN single crystal layer 14 into which hydrogen ions have been implanted is in a hydrogen-embrittled state, so it can be easily detached by heating. Moreover, instead of heating the AlN single crystal substrate 16 and the AlN single crystal layer 14, mechanical detachment may be performed by inserting a blade into the hydrogen-embrittled portion into which hydrogen ions have been implanted. Finally, if necessary, the surfaces of the detached AlN single crystal substrate 16 and AlN single crystal layer 14 can be polished.

As described above, the AlN single crystal layer 14 and the support substrate 12 can be bonded by direct bonding. In this case, it is preferable to increase the bonding strength by irradiating each bonding surface of the AlN single crystal layer 14 and the support substrate 12 with a neutral atomic beam such as an Ar beam to activate the surface (see, for example, Patent Literature 4 (JP7295351B)). It is preferable to perform the surface activation using a neutral atomic beam by generating a neutral atomic beam using a known device such as that disclosed in Patent Literature 6 (JP2014-086400A), and irradiating the neutral atomic beam onto each bonding surface. That is, a saddle-field type fast atom beam source is used as the beam source. An inert gas is introduced into the chamber, and a high voltage is applied to the electrodes from a DC power supply. As a result, a saddle-field type electric field is generated between the electrode (positive electrode) and the housing (negative electrode), which causes the electrons to move, generating a beam of atoms and ions from the inert gas. Of the beams that reach the grid, the ion beam is neutralized by the grid, and a beam of neutral atoms is emitted from the fast atom beam source. The atomic species that make up the beam are preferably inert gases (argon, nitrogen, and the like). The voltage during activation by beam irradiation is preferably 0.5 to 2.0 KV, and the current is preferably 50 to 200 mA. Next, the activated bonding surfaces are brought into contact with each other in a vacuum atmosphere, thereby bonding the AlN single crystal layer 14 and the support substrate 12. The temperature during bonding may be ordinary temperature, but specifically, the temperature is preferably 40° C. or less, more preferably 30° C. or less, and further preferably 20 to 25° C. The pressure load during bonding is preferably 100 to 20000 N. Further, the bonding surfaces of the AlN single crystal layer 14 and the support substrate 12 are preferably as flat as possible because this enables higher bonding strength. Alternatively, as described above, the bonding strength can be increased by activating the bonding surfaces with plasma such as nitrogen gas plasma (plasma activation method), as proposed in Patent Literature 5 (WO 2022/190465).

As described above, the AlN single crystal layer 14 and the support substrate 12 can also be bonded by indirect bonding. In this case, bonding can be performed in the same manner as the direct bonding described above, except that the bonding layer 18 is interposed between the support substrate 12 and the AlN single crystal layer 14, like in the composite substrate 10′ shown in FIG. 3. The bonding layer 18 is preferably formed by a vapor deposition method such as sputtering. After forming the bonding layer 18, a bonded body of the support substrate 12/bonding layer 18/AlN single crystal layer 14 can be obtained with high bonding strength by performing the same process as for the direct bonding described above.

### Device

A device can also be produced using the composite substrate 10 or AlN single crystal layer 14 of the present invention. That is, a device that preferably includes the composite substrate 10 or the AlN single crystal layer 14 is provided. Examples of such a device include a deep ultraviolet laser diode, a deep ultraviolet diode, a power electronic device, a high-frequency device, a heat sink, and the like. The method for producing the device using the composite substrate 10 or AlN single crystal layer 14 is not particularly limited, and the device can be produced using a known method.

### EXAMPLES

The present invention will now be described in more detail with reference to the following examples. However, the present invention is not limited to these examples.

### Examples 1 to 20

### (1) Formation of AlN Single Crystal Layer

Disk-shaped AlN single crystals (of various known crystal qualities) having a thickness of 600 μm (Examples 1 to 12) or 400 μm (Examples 13 to 20) and a diameter of 100 mm (Examples 1 to 5 and 7 to 12), 150 mm (Example 6), or 50 mm (Examples 13 to 20) were prepared as seed crystals for growing AlN single crystal layers. An AlN single crystal layer was grown on an AlN single crystal (seed crystal) by HVPE using the HVPE apparatus shown in FIG. 4. Specifically, the HVPE apparatus includes the reactor 40, susceptor 44, carrier gas supply source 46, Al raw material supply source 48, metal Al powder raw material 50 arranged in the Al raw material supply source 48, heater 52, and gas exhaust 54. In the HVPE apparatus, an AlN single crystal substrate 16 (seed crystal) was arranged on the susceptor 44 so that the N surface (Examples 1 to 7 and 9 to 20) or the Al surface (Example 8) was exposed. AlCl₃ gas, which was obtained by supplying HCl gas to the Al raw material supply source 48 that had been heated to 600° C., and NH₃ gas from the carrier gas supply source 46 were mixed and supplied to the AlN single crystal substrate 16. An AlN single crystal layer was grown under the following conditions. In this way, a composite material (hereinafter referred to as “AlN composite material”) was obtained in which an AlN single crystal layer was formed on an AlN single crystal (seed crystal).

### <HVPE Conditions>

AlCl₃ supply partial pressure: 4.0×10⁻⁴ atm
NH₃ supply partial pressure: 2.0×10⁻⁴ atm
AlN growth temperature (formation temperature): 1450° C. (Examples 1 to 8 and 12 to 20) or 1100° C. (Examples 9 to 11)
Formation time: time required for the AlN single crystal layer to reach a thickness of 1 μm or more (Example 13), 2 μm or more (Examples 1 to 6, 8 to 12, and 14 to 20), or 100 μm or more (Example 7)

To mirror-finish the surface of the obtained AlN single crystal layer, the layer surface was smoothed by lapping using diamond abrasive grains, and then polished by chemical mechanical polishing (CMP) using colloidal silica or the like. In this way, an AlN single crystal substrate with a mirror-finished surface was obtained.

### (2) Transfer of AlN Single Crystal Layer

This AlN single crystal layer was detached by ion implantation (Examples 1 to 6 and 8 to 12) or by using a wire (Example 7), and directly bonded to the support substrate (Examples 1 to 11) or indirectly bonded via SiO₂ (Examples 12 to 14 and 18), Al₂O₃ (Example 15), SiC (Examples 16 and 19), or Ta₂O₅ (Examples 17 and 20). As the support substrate, a 600 μm-thick polycrystalline AlN substrate (Examples 1 to 3 and 7 to 12), a 600 μm-thick sapphire substrate (Examples 4, 6 and 18 to 20), a 600 μm-thick silicon substrate (Example 5), or a 400 μm-thick quartz substrate (Examples 13 to 17) was used, as shown in Table 1. The specific procedure was as follows.

### Examples 1 to 6 and 8 to 11

First, a hydrogen ion beam was irradiated onto the surface of the AlN single crystal layer using an ion implanter to implant hydrogen ions to a desired depth. This resulted in hydrogen embrittlement of the AlN single crystal layer at the desired depth. Next, a fast Ar neutral atom beam (acceleration voltage: 1 kV, Ar flow rate: 60 sccm) was irradiated onto the surface of the AlN single crystal layer and onto the surface of the support substrate for 70 seconds to activate these surfaces. The AlN composite material and the support substrate were overlapped so that the AlN single crystal layer and the support substrate were in contact with each other, and a load of 1000 N was applied under vacuum to bond the AlN composite material (in particular the AlN single crystal layer) to the support substrate. The resulting bonded body was heated at 500° C., and the AlN single crystal layer was detached from the AlN single crystal (seed crystal) together with the support substrate at the hydrogen ion implanted portion. In this way, the AlN single crystal layer was transferred onto the support substrate. The surface of the obtained composite material was smoothed by lapping using diamond abrasive grains or chemical mechanical polishing (CMP) using colloidal silica or the like to obtain a composite substrate composed of a support substrate and an AlN single crystal layer. The composite substrate was disk-shaped, and had a diameter of 100 mm in Examples 1 to 5 and 8 to 11, and 150 mm in Example 6. The thickness of the AlN seed crystal layer was 2 μm in all Examples 1 to 6 and 8 to 11, and the thickness of the composite substrate was 602 μm in Examples 1 to 6 and 8 to 11.

### Example 7

A fast Ar neutral atom beam (acceleration voltage: 1 kV, Ar flow rate: 60 sccm) was irradiated onto the surface of the AlN single crystal layer and onto the surface of the support substrate for 70 seconds to activate these surfaces. The AlN composite material and the support substrate were overlapped so that the AlN single crystal layer and the support substrate were in contact with each other, and a load of 1000 N was applied under vacuum to bond the AlN composite material (in particular the AlN single crystal layer) to the support substrate. Next, the AlN single crystal layer was detached from the AlN single crystal (seed crystal) together with the support substrate by using a diamond wire saw. In this way, the AlN single crystal layer was transferred onto the support substrate. The surface of the obtained composite material was smoothed by lapping using diamond abrasive grains or chemical mechanical polishing (CMP) using colloidal silica or the like to obtain a composite substrate composed of a support substrate and an AlN single crystal layer. In this way, a composite substrate composed of a support substrate and an AlN single crystal layer was obtained. The composite substrate was disk-shaped, and had a diameter of 100 mm. The thickness of the AlN seed crystal layer was 100 μm, and the thickness of the composite substrate was 700 μm.

### Examples 12 and 13

First, a hydrogen ion beam was irradiated onto the surface of the AlN single crystal layer using an ion implanter to implant hydrogen ions to a desired depth. This resulted in hydrogen embrittlement of the AlN single crystal layer at the desired depth. Next, a 1 μm-thick SiO₂ film was formed on the surface of the AlN single crystal layer by sputtering to obtain a SiO₂/AlN composite material. The surface of the SiO₂ film was polished and flattened by chemical mechanical polishing (CMP). The SiO₂/AlN composite and the support substrate were placed in a plasma activation chamber, and the surfaces of the SiO₂ film and the support substrate were activated with nitrogen gas plasma at 30° C. This surface activation was carried out for 40 seconds with an energy of 100 W. The SiO₂/AlN composite material and the support substrate were overlapped so that the activated surfaces were in contact with each other, then pressurized at 0.3 MPa and heated in an oven in a nitrogen atmosphere at 130° C. for 4 hours to bond the SiO₂/AlN composite material (in particular the SiO₂ film) to the support substrate. The resulting bonded body was heated at 500° C., and the AlN single crystal layer and the SiO₂ film were detached from the AlN single crystal (seed crystal) together with the support substrate at the hydrogen ion implanted portion. In this way, the AlN single crystal layer was transferred onto the support substrate together with the SiO₂ film. The surface of the obtained composite material was smoothed by lapping using diamond abrasive grains to obtain a composite substrate composed of a support substrate, a SiO₂ film (bonding layer), and an AlN single crystal layer. The composite substrate was disk-shaped, and had a diameter of 100 mm (Example 12) or 50 mm (Example 13). The thickness of the AlN seed crystal layer was 2 μm, and the thickness of the composite substrate was 602 μm (Example 12) or 401 μm ((Example 13).

### Examples 14 to 20

First, a hydrogen ion beam was irradiated onto the surface of the AlN single crystal layer using an ion implanter to implant hydrogen ions to a desired depth. This resulted in hydrogen embrittlement of the AlN single crystal layer at the desired depth. Next, a 1 μm-thick SiO₂ film (Examples 14 and 18), Al₂O₃ film (Example 15), SiC film (Examples 16 and 19), or Ta₂O₅ film (Examples 17 and 20) was formed on the surface of the AlN single crystal layer by sputtering to obtain a SiO₂/AlN composite material (Examples 14 and 18), an Al₂O₃/AlN composite material (Example 15), a SiC/AlN composite material (Examples 16 and 19), or a Ta₂O₅/AlN composite material (Examples 17 and 20). The surface of the SiO₂ film, Al₂O₃ film, SiC film, or Ta₂O₅ film was polished and flattened by chemical mechanical polishing (CMP). The surface of the SiO₂ film, Al₂O₃ film, SiC film, or Ta₂O₅ film of the composite materials and the surface of the support substrate (quartz substrates (Examples 14 to 17) or sapphire substrate (Examples 18 to 20)) were activated by irradiating the surfaces with a fast Ar neutral atom beam (accelerating voltage: 1 kV, Ar flow rate: 60 sccm) for 70 seconds. The AlN composite material and the support substrate were overlapped so that the AlN single crystal layer and the support substrate were in contact with each other, and a load of 1000 N was applied under vacuum to bond the AlN composite material (in particular the AlN single crystal layer) to the support substrate. The resulting bonded body was heated at 500° C., and the AlN single crystal layer was detached from the AlN single crystal (seed crystal) together with the support substrate at the hydrogen ion implanted portion. In this way, the AlN single crystal layer was transferred onto the support substrate together with the SiO₂ film, Al₂O₃ film, SiC film, or Ta₂O₅ film. The surface of the obtained composite material was smoothed by lapping using diamond abrasive grains to obtain a composite substrate composed of a support substrate, a bonding layer (SiO₂ film, Al₂O₃ film, SiC film, or Ta₂O₅ film), and an AlN single crystal layer. The composite substrate was disk-shaped, and had a diameter of 50 mm. The thickness of the AlN seed crystal layer was 2 μm, and the thickness of the composite substrate was 402 μm (Examples 14 to 17) or 602 μm (Examples 18 to 20).

### (3) Evaluations

The following evaluations were performed on the obtained composite substrates.

### (3a) X-Ray Rocking Curve Full Width at Half Maximum

XRC measurement was performed on the (0002) plane of the AlN single crystal layer surface (the surface opposite the support substrate) using a multi-function high-resolution X-ray diffractometer (Bruker-AXS, D8 DISCOVER). The XRC measurement conditions were as follows.

### <XRD Measurement Conditions>

Tube voltage: 40 kV
Tube Current: 40 mA
Detector: Tripple Ge (220) Analyzer
CuKα X-rays collimated and monochromated (full width at half maximum 28 seconds) using a Ge (022) asymmetric reflection monochromator
Step Width: 0.001°
Scan speed: 0.5 seconds/step

In practice, the axis was adjusted by adjusting 2θ, ω, χ, and φ so that the peak of the (0002) plane of the AlN single crystal was obtained, and then measurements were taken over the range of ω=14.5 to 19.5° with a 3 mm anti-scattering slit. The full width at half maximum of the XRC profile of the (0002) plane of the obtained AlN single crystal was determined by smoothing the profile and then performing a peak search using XRD analysis software (LEPTOS Ver. 4.03, by Bruker-AXS). As a result, the full width at half maximum of the XRC profile of the (0002) plane of the surface of the AlN single crystal substrate was as shown in Table 1.

XRC measurements were also performed on the (10-12) plane of the surface of the AlN single crystal layer (the surface opposite the support substrate). Using a Bruker-AXS D8-DISCOVER XRD device, the axis was set by adjusting 2θ, ω, χ, and φ so that the peak of the (10-12) plane of the AlN single crystal appeared, and then measurements were performed with ω=24.5-29.5°. Other conditions and analysis methods were the same as those used for the XRC measurement of the (0002) plane. As a result, the full width at half maximum of the (10-12) plane XRC profile of the surface of the AlN single crystal substrate was as shown in Table 1.

### (3b) Defect Density

The defect density of the surface of the obtained AlN single crystal layer (the surface opposite the support substrate) was evaluated by measuring the entire surface area using X-ray topography (XRTmicron, manufactured by Rigaku Corporation). When the defect density is 1.0×10⁵ cm⁻² or more, it is difficult to accurately calculate the number of etch pits using X-ray topography, so etch pit evaluation was performed using KOH molten etching to measure the defect density on the surface of the AlN single crystal layer. Specifically, for the evaluation of etch pits, the surface of the AlN single crystal layer was immersed for 5 minutes in a molten mixture of KOH and NaOH that had been mixed in a weight ratio of 1:1 and heated to 450° C., and then etched, after which the defect density was measured using an optical microscope. The results are shown in Table 1.

### (3c) Detachability Evaluation

For each example, a total of 10 composite substrates were prepared in the same manner as in (1) and (2) above. These composite substrates were heated in an N₂ atmosphere at 1000° C. for 5 minutes, and examined for the presence/absence of detachment of the AlN single crystal layer from the support substrate. Evaluation was carried out according to the following criteria by counting the number of composite substrates in which detachment occurred out of the ten composite substrates. The results are shown in Table 1.
A: No detachment occurred in 7 to 10 of the composite substrates.
B: No detachment occurred in 1 to 6 of the composite substrates.
C: No detachment occurred in 0 of the composite substrates (detachment occurred in all of the composite substrates).

As shown in Table 1, in Examples 1 to 8 and 12 to 20, in which the XRC full width at half maximum of the (0002) plane was within the range of 20 to 350 arcsec, the XRC full width at half maximum of the (10-12) plane was within the range of 20 to 500 arcsec, and the defect density was within the range of 1.0×10³ to 1.0×10⁷ cm⁻², the detachment evaluation was A or B, and composite substrates were obtained in which a high-quality AlN single crystal layer was firmly bonded to an inexpensive support substrate. In contrast, in Examples 9 to 11, in which HVPE was performed at a formation temperature of 1100° C., an AlN single crystal layer with poor crystallinity and defect density was formed, and this poor-quality AlN single crystal layer was transferred onto the support substrate. As a result, the detachability evaluation was also poor, with a C evaluation. It is noted that the varying crystal quality between Examples 1 to 8 and 12 to 20 (Examples) was achieved primarily by using AlN single crystals (seed crystals) of various crystal quality, and the varying crystal quality of Examples 1 to 8 and 12 to 20 (Examples) with Examples 9 to 11 (Comparative Examples) was achieved by changing the HVPE deposition temperature.

TABLE 1

| | | AlN Single Crystal Layer | | | | | | | |
|---|---|---|---|---|---|---|---|---|---|
| | | XRC(0002) | XRC(10-12) | | | | | | |
| | Composite | full width | full width | Defect | | | | | |
| | Substrate | at half | at half | density | | | | | Detachability |
| | Diameter | maximum | maximum | (×10⁶ | Thickness | Exposed | Bonding | Support Substrate | Evaluation |
| | (mm) | (arcsec) | (arcsec) | cm⁻²) | (μm) | plane | Layer | Material type | Result |
| Ex. 1 | 100 | 140 | 220 | 4.0 | 2 | Al plane | — | polycrystalline AlN | A |
| Ex. 2 | 100 | 320 | 490 | 7.0 | 2 | Al plane | — | polycrystalline AlN | B |
| Ex. 3 | 100 | 30 | 40 | 0.02 | 2 | Al plane | — | polycrystalline AlN | B |
| Ex. 4 | 100 | 140 | 220 | 4.0 | 2 | Al plane | — | sapphire | A |
| Ex. 5 | 100 | 140 | 220 | 4.0 | 2 | Al plane | — | Si | A |
| Ex. 6 | 150 | 160 | 240 | 4.4 | 2 | Al plane | — | sapphire | A |
| Ex. 7 | 100 | 140 | 220 | 4.0 | 100 | Al plane | — | polycrystalline AlN | A |
| Ex. 8 | 100 | 140 | 220 | 4.0 | 2 | N plane | — | polycrystalline AlN | A |
| Ex. 9* | 100 | 400 | 600 | 11.0 | 2 | Al plane | — | polycrystalline AlN | C |
| Ex. 10* | 100 | 360 | 550 | 9.0 | 2 | Al plane | — | polycrystalline AlN | C |
| Ex. 11* | 100 | 140 | 220 | 20.0 | 2 | Al plane | — | polycrystalline AlN | C |
| Ex. 12 | 100 | 320 | 490 | 7.0 | 2 | Al plane | SiO₂ | polycrystalline AlN | A |
| Ex. 13 | 50 | 320 | 490 | 7.0 | 1 | Al plane | SiO₂ | quartz | A |
| Ex. 14 | 50 | 320 | 490 | 7.0 | 2 | Al plane | SiO₂ | quartz | A |
| Ex. 15 | 50 | 320 | 490 | 7.0 | 2 | Al plane | Al₂O₃ | quartz | A |
| Ex. 16 | 50 | 320 | 490 | 7.0 | 2 | Al plane | SiC | quartz | A |
| Ex. 17 | 50 | 320 | 490 | 7.0 | 2 | Al plane | Ta₂O₅ | quartz | A |
| Ex. 18 | 50 | 320 | 490 | 7.0 | 2 | Al plane | SiO₂ | sapphire | A |
| Ex. 19 | 50 | 320 | 490 | 7.0 | 2 | Al plane | SiC | sapphire | A |
| Ex. 20 | 50 | 320 | 490 | 7.0 | 2 | Al plane | Ta₂O₅ | sapphire | A |

The asterisk * indicates a comparative example.

### REFERENCE SIGNS LIST

10, 10′ composite substrate
12 support substrate
14 AlN single crystal layer
16 AlN single crystal substrate
18 bonding layer
40 reactor
44 susceptor
46 carrier gas supply source
48 Al raw material supply source
50 metal Al powder raw material
52 heater
54 gas exhaust

What is claimed is:

1. A composite substrate comprising:
a support substrate; and
an AlN single crystal layer bonded to the support substrate,
wherein the AlN single crystal layer has, on an exposed surface opposite the support substrate,
an X-ray rocking curve full width at half maximum of a (0002) plane of 20 to 350 arcsec,
an X-ray rocking curve full width at half maximum of a (10-12) plane of 20 to 500 arcsec, and
a defect density of 1.0×10³ to 1.0×10⁷ cm⁻²,
wherein the composite substrate further comprises, between the support substrate and the AlN single crystal layer, a bonding layer including at least one selected from the group consisting of aluminum nitride, alumina, silicon carbide, silicon dioxide, and tantalum pentoxide, whereby the AlN single crystal layer is indirectly bonded to the support substrate.

2. The composite substrate according to claim 1, wherein the composite substrate has a size of 50 mm or more in diameter.

3. The composite substrate according to claim 1, wherein the support substrate is composed of one selected from the group consisting of polycrystalline aluminum nitride, sapphire, silicon carbide, quartz, and a Si substrate.

4. A composite substrate comprising:
a support substrate; and
an AlN single crystal layer bonded to the support substrate,
wherein the AlN single crystal layer has, on an exposed surface opposite the support substrate,
an X-ray rocking curve full width at half maximum of a (0002) plane of 20 to 350 arcsec,
an X-ray rocking curve full width at half maximum of a (10-12) plane of 20 to 500 arcsec, and
a defect density of 1.0×10³ to 1.0×10⁷ cm⁻²,
wherein the AlN single crystal layer is directly bonded to the support substrate, and wherein the support substrate and the AlN single crystal layer contain Ar in a layered region including a bonding interface between the support substrate and the AlN single crystal layer.

5. The composite substrate according to claim 4, wherein the composite substrate has a size of 50 mm or more in diameter.

6. The composite substrate according to claim 4, wherein the support substrate is composed of one selected from the group consisting of polycrystalline aluminum nitride, sapphire, silicon carbide, quartz, and a Si substrate.

7. A device comprising the composite substrate according to claim 1.

8. A device comprising the composite substrate according to claim 4.
